(19) United States
(12) Patent Application Publication
(10) Pub. No.: US 2008/0238496 A1
(43) Pub. Date: Oct. 2, 2008

(54) Current mode receiver

(75) Inventor: Chih-Haur Huang, Tainan (TW)

Correspondence Address: BACON & THOMAS, PLLC, 625 SLATERS LANE, FOURTH FLOOR, ALEXANDRIA, VA, 22314-1176, US

(73) Assignee: HIMAX TECHNOLOGIES LIMITED, Tainan (TW)

(21) Appl. No.: 11/730,233

(22) Filed: Mar. 30, 2007

(51) Int. Cl. H03B 1/00

(52) U.S. Cl. 327/108

(57) ABSTRACT

A current mode receiver is provided. The current mode receiver includes a first current mirror duplicating an input current to output a first output current, a second current mirror duplicating the first output current to output a second output current, a third current mirror duplicating a reference current to output a third output current, and means for pulling high or low an output voltage based on the second output current and the third output current. The first through third current mirrors are respectively inputted and outputting through gain boost circuits to increase the input and output impedance thereof.

### BACKGROUND OF THE INVENTION

1. Field of the Invention

The invention relates in general to a current mode receiver, and more particularly to a current mode receiver using current mirror with high input and output impedances.

2. Description of the Related Art

FIG. 1 shows a circuit scheme of a conventional current mode receiver 100. The conventional current mode receiver 100 includes current mirrors 110, 120 and 130. The current mirror 110 receives an input current Ii corresponding to the load 140, and duplicates it to output an output current I1. The current mirror 120 receives the output current I1 and duplicates it to output an output current I2. The current mirror 130 receives a reference current Ir, and duplicates it to output an output current I3. The outputs of current mirrors 120 and 130 are connected at a node 150. When the output current I2 is greater than the output current I3, the output voltage Vo at the node 150 is pulled low. When the output current I3 is greater than the output current I2, the output voltage Vo is pulled high. Therefore, ideally, when the input current Ii, equal to the output current I2, is greater than the reference current Ir, equal to the output current I3, the output voltage Vo is pulled low. When the reference current Ir is greater than the input current Ii, the output voltage Vo is pulled high.

However, due to the mismatch of the current mirrors 110, 120 and 130, the output currents I2 and I3 are biased from the input current Ii and the reference current Ir respectively, which would tend to bad duty ratio for the current mode receiver 100.

### SUMMARY OF THE INVENTION

The invention is directed to a current mode receiver. The input and output impedances of the current mirrors used in the current mode receiver are increased by the gain boost circuits, such that the mismatch occurred in the current mirrors is effectively reduced. The current mode receiver hence improves its duty ratio.

According to (a first aspect of) the present invention, a current mode receiver is provided. The current mode receiver includes a first current mirror duplicating an input current to output a first output current, a second current mirror duplicating the first output current to output a second output current, a third current mirror duplicating a reference current to output a third output current, and means for pulling high or low an output voltage based on the second output current and the third output current. The first through third current mirrors are respectively inputted and outputting through gain boost circuits to increase the input and output impedance thereof.

The invention will become apparent from the following detailed description of the preferred but non-limiting embodiments. The following description is made with reference to the accompanying drawings.

### BRIEF DESCRIPTION OF THE DRAWINGS

FIG. 1 shows a circuit scheme of a conventional current mode receiver.

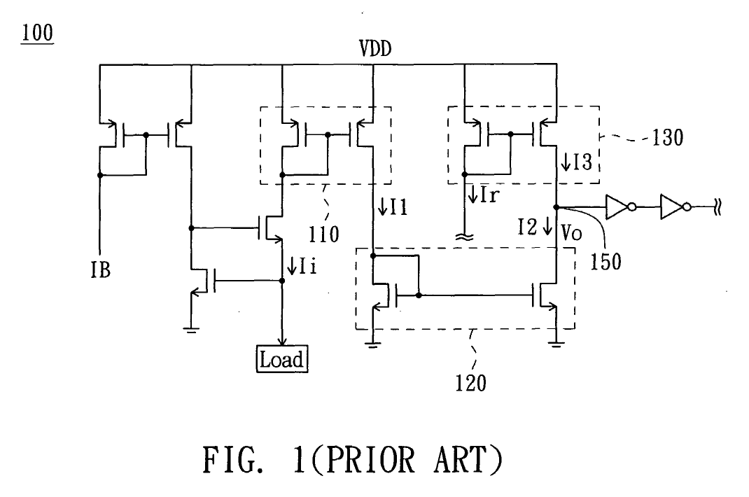

FIG. 2 shows the circuit scheme of the current mode receiver 200 according to the embodiment of the present invention

### DETAILED DESCRIPTION OF THE INVENTION

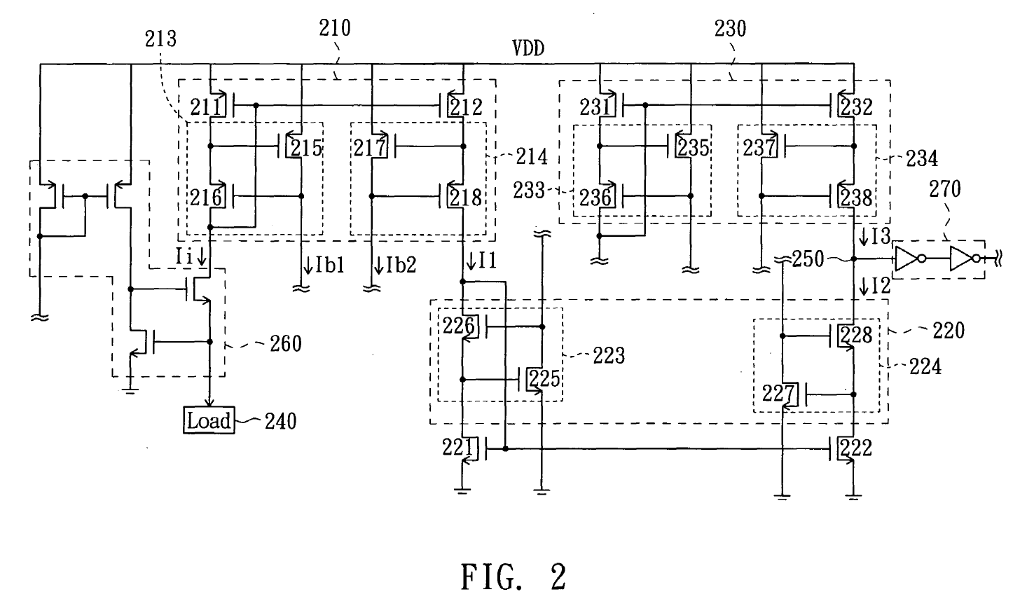

Referring to FIG. 2, the circuit scheme of the current mode receiver 200 according to the embodiment of the present invention is shown. The current mode receiver is for outputting a high or low output voltage Vo according to an input current Ii corresponding to a load 240 with reference to a reference current Ir. The current mode receiver 200 includes current mirrors 210, 220, 230, and means for pulling high or low the output voltage Vo.

The current mirror 210 is for duplicating an input current Ii to output an output current I1. The current mirror 220 is for duplicating the output current I1 to output an output current I2. The current mirror 230 is for duplicating the reference current Ir to output an output current I3.

In the embodiment of the present invention, the output voltage Vo is at the node 250 formed by the outputs of the current mirror 220 and 230, and is pulled high or low based on the output currents I2 and I3. When the output current I2 is greater than the output current I3, the output voltage Vo is pulled low. When the output current I3 is greater than the output current I2, the output voltage Vo is pulled high.

The current mirrors 210, 220 and 230 are respectively inputted and output through gain boost circuits to increase the input and output impedance of the current mode receiver 200.

In the embodiment of the present invention, the current mirror 210 includes transistors 211 and 212, gain boost circuits 213 and 214. The transistors 211 and 212 form a basic current mirror, and respectively receive the input current Ii and output the output current I1. The gain boost circuits 213 and 214 respectively increase the input and output impedances of the current mirror 210. The reduction of the mismatch of the current mirrors 210 is therefore achieved.

In the embodiment of the present invention, the transistors 211 and 212 are designed to duplicate the input current Ii to output the output current I1. By reduction of the mismatch of the current mirror 210, the output current I1 is sufficiently close to the input current Ii.

In the embodiment of the present invention, the gain boost circuit 213 includes transistors 215 and 216, while the gain boost circuit 214 includes transistors 217 and 218. The gate of the transistor 211 is connected with the gate of the transistor 212 and the drain of the transistor 216. The drain of the transistor 211 is connected with the gate of the transistor 215 and the source of the transistor 216. The drain of the transistor 215 is connected with the gate of the transistor 216.

The drain of the transistor 212 is connected with the gate of the transistor 217 and the source of the transistor 218. The drain of the transistor 217 is connected with the gate of the transistor 218. The drains of the transistors 215 and 217 respectively receive bias currents Ib2 and Ib3. The drains of the transistors 216 and 218 of the current mirror 210 respectively receive the input current Ii and output the output current I1.

Similarly, in the embodiment of the present invention, the current mirror 220 includes transistors 221 and 222, gain boost circuits 223 and 224, while the current mirror 230 includes transistors 231 and 232, gain boost circuits 233 and 234. The function and the connection of the transistors and gain boost circuits in the current mirrors 220 and 230 are similar to those in the current mirror 210. The input and output impedances of the current mirrors 220 and 230 are increased, such that the mismatch thereof are reduced.

The transistor 221 and 222 in the embodiment of the present invention are designed to duplicate the output current I1 to output the output current I2. By reduction of the mismatch of the current mirror 220, the output current I2 is sufficiently close to the output current I1. Similarly, by reduction of the mismatch of the current mirror 230, the output current I3 generated by the current mirror 230 is sufficiently close to the output current Ir.

In the embodiment of the present invention, the transistors in the current mirror 210 and 230 are exemplified by PMOS, while the transistors in the current mirror 220 are exemplified by NMOS. It is not limited by this in the practical application.

The current mode receiver 200 further includes an input circuit 260. The input circuit 260 is for inputting the input current Ii corresponding to the load 240 into the current mirror 210.

The input and output impedances of the current mirrors 210 through 230 are increased by the gain boost circuits 213, 223, 233, 214, 224 and 234, such that the mismatch occurred in the current mirrors 210 through 230 is effectively reduced. Therefore the output currents I1, I2, and I3 are sufficiently equal to the input current Ii, the output current I1, and the reference current Ir. The current mode receiver hence improves its duty ratio, in comparison with the conventional current mode receiver, whose duty ratio is degraded by the severe mismatch of the conventional current mirrors.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A current mode receiver, comprising:
a first current mirror duplicating an input current to output a first output current;
a second current mirror duplicating the first output current to output a second output current;
a third current mirror duplicating a reference current to output a third output current; and
means pulling high or low an output voltage based on the second output current and the third output current;
wherein the first through third current mirrors are respectively inputted and outputting through gain boost circuits to increase the input and output impedance thereof.

2. The current mode receiver according to claim 1, wherein each of the first through the third current mirrors comprises an input transistor, an output transistor, an input gain boost circuit and an output gain boost circuit respectively for increasing the input impedance and the output impedance thereof, the input transistors of the first through the third current mirrors respectively receiving the input current, the first output current, and the reference current, the output transistors of the first through the third current mirrors respectively output the first through the third output currents.

3. The current mode receiver according to claim 2, wherein the input gain boost circuit of each of the first through the third circuits comprises a first transistor and a second transistor, the output gain boost circuit of each of the first through the third circuits comprises a third transistor and a fourth transistor, the control end of the input transistor is connected with the control end of the output transistor and the second end of the second transistor, the first end of the input transistor is connected with the control end of the first transistor and the first end of the second transistor, the first end of the first transistor is connected with the control end of the second transistor, the first end of the output transistor is connected with the control end of the third transistor and the first end of the fourth transistor, the first end of the third transistor is connected with the control end of the fourth transistor, the first ends of the first and the third transistors respectively receives a bias current, the second ends of the second transistors of the first through the third current mirrors respectively receive the input current, the first output current, and the reference current, the second ends of the fourth transistors of the first through the third current mirrors respectively output the first through the third output currents.

4. The current mode receiver according to claim 1, further comprising an input circuit for inputting the input current corresponding to the load into the first current mirror.

5. The current mode receiver according to claim 1, further comprising an output buffer receiving the output voltage and outputting a buffered output voltage.
